(19) United States
(12) Patent Application Publication
(10) Pub. No.: US 2024/0268071 A1
(43) Pub. Date: Aug. 8, 2024

(54) HEAT DISSIPATION STRUCTURE AND HEAT DISSIPATION ASSEMBLY INCLUDING THE SAME

(71) Applicant: WISTRON CORP., New Taipei City (TW)

(72) Inventors: CHIA-LIAN YEN, New Taipei City (TW); CHIH-CHUN HUANG, New Taipei City (TW)

(21) Appl. No.: 18/346,906

(22) Filed: Jul. 5, 2023

(30) Foreign Application Priority Data
Feb. 8, 2023 (TW) 112104405

(51) Int. Cl. H05K 7/20; G06F 1/20

(52) U.S. Cl. CPC H05K 7/20336; G06F 1/206; H05K 7/2039

(57) ABSTRACT

The disclosure provides a heat dissipation structure and a heat dissipation assembly including the same. The heat dissipation structure includes an accommodation portion and two mount portions. The accommodation portion includes a cover part and two sidewall parts. The cover part is located between and connected to the two sidewall parts. The cover part is located between and connected to the two mount portions by the two sidewall parts. Each of the two sidewall parts is absent of any holes, or the heat dissipation structure has a hollow structure located at the cover part and extending between the two mount portions.

### CROSS-REFERENCE TO RELATED APPLICATIONS

This non-provisional application claims priority under 35 U.S.C. § 119(a) on patent application Ser. No(s). 112/104,405 filed in Taiwan, R.O.C. on Feb. 8, 2023, the entire contents of which are hereby incorporated by reference.

### TECHNICAL FIELD

This disclosure relates to a heat dissipation device, more particularly to a heat dissipation structure and a heat dissipation assembly including the same.

### BACKGROUND

Electronic devices, such as servers, desktop computers and laptop computers, include various heat sources (e.g., CPUs and GPUs). In order to ensure or even improve the performance of those heat sources, heat dissipation is important for normal functioning of the electronic devices.

In this regard, the common way is to use a heat pipe to directly or indirectly thermally contact the heat source, in order to conduct the waste heat generated by the heat source to a distal heat dissipation assembly (e.g., a heat sink) for dissipating heat. In addition, a heat dissipation structure that can be assembled and fixed on a circuit board is usually provided to ensure that the heat pipe can firmly thermally contact the heat source.

However, a conventional heat dissipation structure is made of sheet metal, and a groove thereon used to accommodate the heat pipe is usually formed by bending the sheet metal, but fillets formed after the bending process will increase the gap between the heat pipe and the heat dissipation structure, causing the heat dissipation structure to be unable to fully contact the heat pipe, thereby adversely affecting the heat dissipation of the heat pipe.

### SUMMARY

Accordingly, this disclosure provides a heat dissipation structure and a heat dissipation assembly including the same, which are capable of addressing the problem of deteriorated heat dissipation of the heat pipe by the conventional heat dissipation structure, caused by the increased gap between the heat pipe and the heat dissipation structure due to the thermal contact area therebetween being reduced by the fillets formed after the bending process.

One embodiment of the disclosure provides a heat dissipation structure. The heat dissipation structure includes an accommodation portion and two mount portions. The accommodation portion includes a cover part and two sidewall parts. The cover part is located between and connected to the sidewall parts. The cover part is located between and connected to the mount portions via the sidewall parts, and each of the sidewall parts has a solid body located between opposite ends of the cover part.

One embodiment of the disclosure provides a heat dissipation structure. The heat dissipation structure includes an accommodation portion and two mount portions. The accommodation portion includes a cover part and two sidewall parts. The cover part is located between and connected to the sidewall parts. The cover part is located between and connected to the mount portions via the sidewall parts. The heat dissipation structure has a hollow structure located at the cover part and extending between the two mount portions.

One embodiment of the disclosure provides a heat dissipation assembly. The heat dissipation assembly includes a heat dissipation structure, a heat pipe and a heat sink. The heat dissipation structure includes an accommodation portion and two mount portions. The accommodation portion includes a cover part and two sidewall parts. The cover part is located between and connected to the sidewall parts. The cover part is located between and connected to the mount portions via the sidewall parts. A section of each of the sidewall parts located between opposite ends of the cover part is absent of any holes. The cover part is absent of any holes. The heat pipe is partially disposed in the accommodation portion of the heat dissipation structure and in thermal contact with the cover part and the sidewall parts. The heat sink is in thermal contact with the heat pipe.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is an exploded view of a heat dissipation assembly applied to an electronic component in accordance with one embodiment of the disclosure;

FIG. 2 is another perspective view of the heat dissipation assembly in FIG. 1;

FIG. 3 and FIG. 4 are various perspective views of a heat dissipation structure in FIG. 2;

FIG. 5 is a cross-sectional view of the heat dissipation structure and a heat pipe in FIG. 1;

FIG. 6 is one manufacturing schematic view of the heat dissipation structure in accordance with the above described embodiment;

FIG. 7 is a perspective view of a heat dissipation structure in accordance with another embodiment of the disclosure;

FIG. 8 is a partial and enlarged view of the heat dissipation structure in FIG. 7;

FIG. 9 is a partial, enlarged and sectional view of the heat dissipation structure in FIG. 7 applied to a heat pipe;

FIG. 10 is a perspective view of a heat dissipation structure applied to a heat pipe in accordance with another embodiment of the disclosure;

FIG. 11 is an exploded view of the heat dissipation structure in FIG. 10;

FIG. 12 is a partial, enlarged and sectional view of the heat dissipation structure and the heat pipe in FIG. 10;

FIG. 13 is a perspective view of a heat dissipation structure applied to a heat pipe in accordance with another embodiment of the disclosure;

FIG. 14 is an exploded view of the heat dissipation structure in FIG. 13;

FIG. 15 is a partial, enlarged and sectional view of the heat dissipation structure and the heat pipe in FIG. 13; and

FIG. 16 is a perspective view of a heat dissipation structure in accordance with another embodiment of the disclosure.

### DETAILED DESCRIPTION

Aspects and advantages of the disclosure will become apparent from the following detailed descriptions with the accompanying drawings. The inclusion of such details provides a thorough understanding of the disclosure sufficient to enable one skilled in the art to practice the described embodiments but it is for the purpose of illustration only and should not be understood to limit the disclosure. On the contrary, it is intended to cover alternatives, modifications, and equivalents as can be included within the spirit and scope of the described embodiments as defined by the appended claims. To this end, those skilled in the relevant art will recognize and appreciate that many changes can be made to the various aspects of the disclosure described herein, while still obtaining the beneficial results of the present disclosure. It will also be apparent that some of the desired benefits of the present disclosure can be obtained by selecting some of the features of the present disclosure without utilizing other features.

The following embodiments will be described with the accompanying drawings. In order to achieve a neat and clear appearance of the drawings, some commonly used structures and components may be depicted in a simplified manner in the drawings. Additionally, some features in the drawings may be slightly enlarged or altered in proportion or size to facilitate the understanding and observation of the technical features of the present disclosure, but the present disclosure is not limited thereto. Furthermore, for the purpose of clarity, certain structural lines in some of the drawings may be shown in dotted lines or be omitted. Moreover, a coordinate system is provided in the drawings to facilitate understanding of the viewing angle.

It is to be understood that the phraseology and terminology used herein are for the purpose of better understanding the descriptions and should not be regarded as limiting. In addition, terms such as “end,” “part,” “portion,” “region,” and “area” may be used herein to describe specific components and structures or specific technical features thereon or therebetween, but these components and structures are not limited by these terms. Terms such as “substantially,” “approximately,” and “generally” may also be used herein to describe reasonable or acceptable deviations that may exist in situations or events that are modified, but still achieve the expected results. Terms such as “path” or “pipeline” may also be used herein, which refer to any component in a liquid cooling system that allows the cooling fluid to flow and form a cooling cycle, such as flow tubes, pumps, or cold plates.

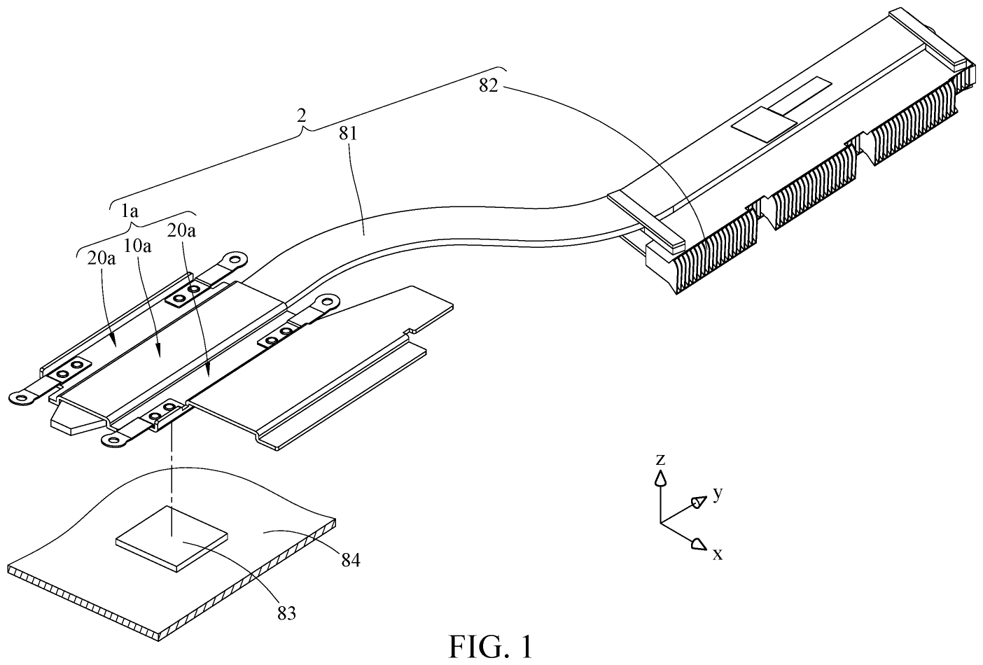

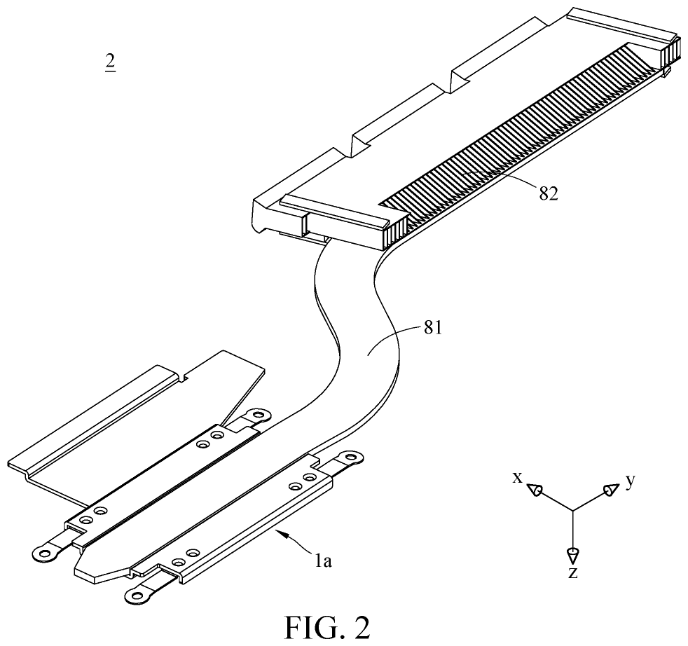

Firstly, please refer to FIG. 1 to FIG. 2. One embodiment of the disclosure provides a heat dissipation assembly 2, and the heat dissipation assembly 2 is configured to dissipate heat generated by one or more electronic components 83 disposed on a printed circuit board (PCB) 84. The electronic component 83 may be, but not limited to, an electronic component which generates waste heat during operation and needs to be cooled. For example, the electronic component 83 may be a central processing unit (CPU), but the electronic component 83 is only exemplary, and the present disclosure is not limited thereto. The PCB 84 may be, but not limited to, a circuit board structure carrying various desired electronic components in a well-known server, computer host, or laptop computer, but the PCB 84 is only exemplary, and the present disclosure is not limited thereto.

Furthermore, in this embodiment, the heat dissipation assembly 2 may include a heat dissipation structure 1a, a heat pipe 81 and a heat sink 82. The heat pipe 81 may be, but not limited to, a component made of a suitable material having desired thermal conductivity, so the heat pipe 81 is suitable to thermally contact the electronic component 83 so as to constantly absorb and conduct waste heat generated by the electronic component 83, but the heat pipe 81 is only exemplary, and the disclosure is not limited to its specification, material or size. The heat sink 82 can be in thermal contact with the heat pipe 81. Specifically, the heat sink 82 can be in thermal contact with a part of the heat pipe 81 located relatively far away from the electronic component 83 so as to absorb heat absorbed by the heat pipe 81 and dissipate the heat. The heat dissipation structure 1a is suitable for fixing at least a part of the heat pipe 81 to the PCB 84, so that the heat pipe 81 can be firmly in thermal contact with the electronic component 83 on the PCB 84. In specific, the heat dissipation structure 1a and the heat pipe 81 may be connected to each other via a suitable means, such as adhesives or a welding process, and the heat dissipation structure 1a may be fixed to the PCB 84 via a suitable means, such as screws or bolts, so as to ensure and keep the heat pipe 81 in thermal contact with the electronic component 83 in a predetermined manner. The following paragraphs introduce the heat dissipation structure 1a in detail.

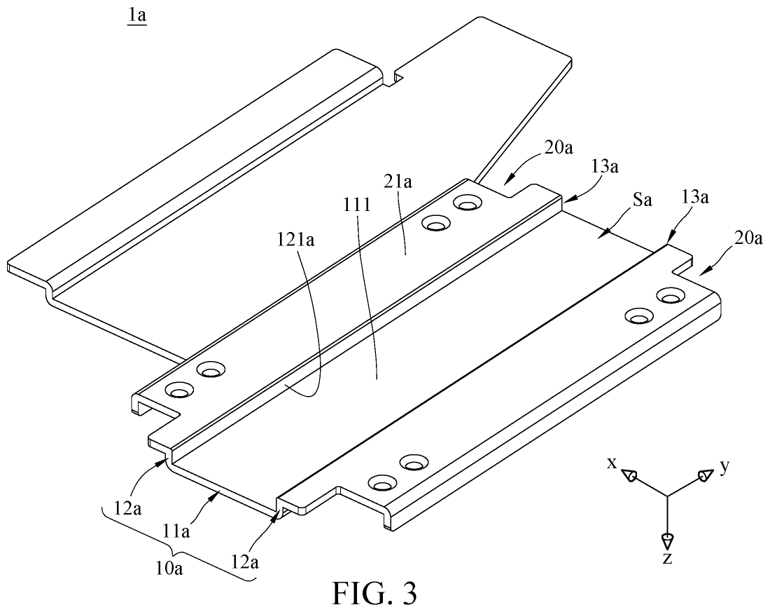

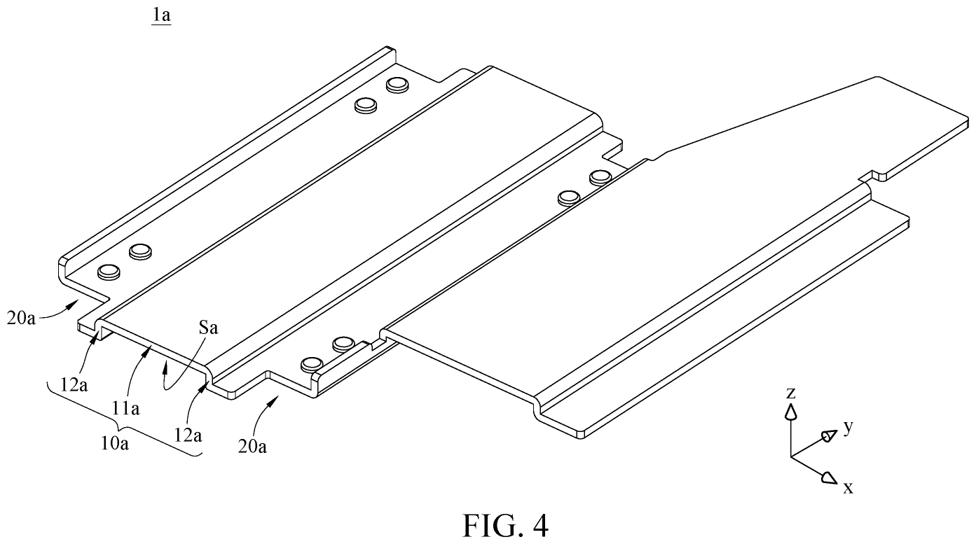

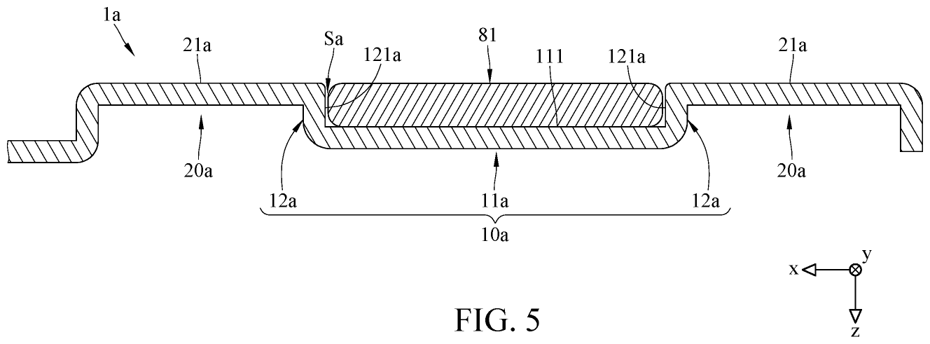

Please refer to FIG. 3 to FIG. 6. In this embodiment, the heat dissipation structure 1a may be, but not limited to, integrally formed by a suitable material having desired thermal conductivity. Generally, the heat dissipation structure 1a may include an accommodation portion 10a and two mount portions 20a. The accommodation portion 10a is located between and connected to the mount portions 20a. The accommodation portion 10a refers to a portion of the heat dissipation structure 1a configured to receive a part of the heat pipe 81; in other words, a part of the heat pipe 81 can be accommodated in the accommodation portion 10a. Furthermore, the shape of the accommodation portion 10a substantially matches the shape of the part of the heat pipe 81. The mount portions 20a refers to portions of the heat dissipation structure 1a suitable to be fixed to the PCB 84 by a suitable means such as screws or bolts. As a result, the accommodation portion 10a can be fixed to the PCB 84 via the mount portions 20a. As shown in the figures, each of the mount portions 20a may have a mount surface 21a, and the mount surfaces 21a refer to surfaces of the mount portions 20a that are suitable to face toward or contact the PCB 84.

Furthermore, in this embodiment, the accommodation portion 10a may include a cover part 11a and two sidewall parts 12a. The cover part 11a is located between and connected to the sidewall parts 12a, and the cover part 11a is connected to the mount portions 20a via the sidewall parts 12a; in other words, the sidewall parts 12a are located between and connected to the cover part 11a and the mount portions 20a, respectively. The cover part 11a and the sidewall parts 12a are formed by, for example, a process of bending a sheet metal, so the cover part 11a can be at an angle to the sidewall parts 12a. For example, the cover part 11a may be substantially perpendicular to the sidewall parts 12a. From the perspective of the figures, the cover part 11a may be, for example, a plate structure extending in the XY-plane, and the sidewall parts 12a may be, for example, plate structures extending in the YZ-plane. According to the matching shape requirement of the accommodation portion 10a with the heat pipe 81, a width of the cover part 11a in the X-direction may be larger than a height of each of the sidewall parts 12a in the Z-direction.

In such configuration, the cover part 11a and the sidewall parts 12a can together surround and define an accommodation space Sa. In specific, the cover part 11a may have a cover surface 111, and the cover surface 111 refers to a surface of the cover part 11a suitable to face toward or contact the heat pipe 81. Each of the sidewall parts 12a may have a sidewall surface 121a, and the sidewall surfaces 121a refer to surfaces of the sidewall parts 12a suitable to face toward or contact the heat pipe 81. The cover surface 111 may be substantially perpendicular to the sidewall surfaces 121a. From the perspective of the figures, the cover surface 111 may be, for example, a surface extending in the XY-plane, and the sidewall surfaces 121a may be, for example, surfaces extending in the YZ-plane. The accommodation space Sa may be surrounded and defined by the cover surface 111 and the sidewall surfaces 121a, which is a space of the accommodation portion 10a configured to receive a part of the heat pipe 81. When at least a part of the heat pipe 81 is accommodated in the accommodation space Sa, the sidewall surfaces 121a of the sidewall parts 12a and the cover surface 111 of the cover part 11a may be in thermal contact with different surfaces of the heat pipe 81, respectively.

In addition, the sidewall parts 12a and the mount portions 20a may also be formed by, for example, a process of bending a sheet metal. As a result, the sidewall parts 12a can be at an angle to the mount portions 20a. For example, the sidewall parts 12a may be substantially perpendicular to the mount portions 20a. From the perspective of the figures, the mount portions 20a may be, for example, plate structures extending in the XY-plane, and the mount surfaces 21a of the mount portions 20a may be, for example, surfaces extending in the XY-plane. In such arrangement, the sidewall surfaces 121a of the sidewall parts 12a may be substantially perpendicular to the mount surfaces 21a of the mount portions 20a, and the cover surface 111 of the cover part 11a may be substantially parallel to the mount surfaces 21a of the mount portions 20a.

Moreover, due to the bending process, a bend portion 13a having a fillet is formed between the mount portions 20a and the sidewall parts 12a of the accommodation portion 10a. Through a further treatment, the bend portion 13a may have a fillet with a relatively small curvature radius so as to ensure a sufficient or larger contact area between the sidewall surfaces 121a of the sidewall parts 12a and the heat pipe 81.

In detail, conventionally, in order to form a recess on a sheet metal for receiving a heat pipe, a bending process is performed to bend the sheet metal. However, after the sheet metal is bent, a fillet is formed at a bend portion of the sheet metal, thereby reducing the thermal contact area between the sheet metal and the heat pipe. For this, in the heat dissipation structure 1a of this embodiment, an additional compression treatment is performed on the bend portions 13a between the mount portions 20a and the sidewall parts 12a so as to reduce the curvature radius of the bend portions 13a.

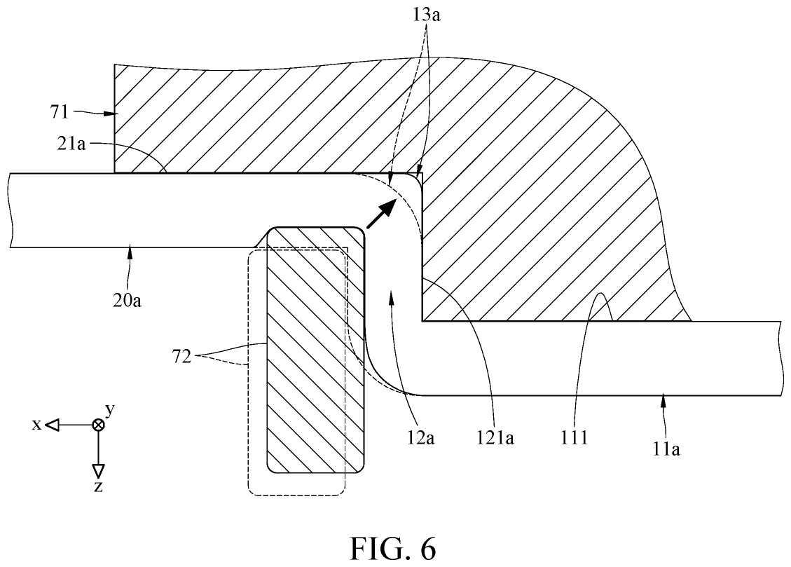

For example, as shown in FIG. 6, the dotted lines illustrate a state of the mount portion 20a, the sidewall part 12a and the bend portion 13a therebetween after a bending process and before a compression treatment; in other words, the bend portion 13a shown in dotted lines is a fillet formed between the mount portion 20a and the sidewall part 12a after the bending process, while the mount portion 20a, the sidewall part 12a and the bend portion 13a shown in solid lines is a state after a compression treatment. In execution, the mount surface 21a of the mount portion 20a and the sidewall surface 121a of the sidewall part 12a may be pressed against a mold 71, and then or simultaneously, a punch 72 may push the bend portion 13a towards the mold 71 from sides of the mount portions 20a and the sidewall parts 12a respectively located opposite to the mount surfaces 21a and the sidewall surfaces 121a, such that the bend portion 13a may be deformed from the shape shown by dotted lines to the shape shown by solid lines having a smaller curvature radius via, for example, a cold forging process. It should be understood that when the bend portion 13a is being squeezed and pushed towards the surface of the mold 71 so as to be deformed, an area of the sidewall surface 121a of the sidewall part 12a can be increased, thereby increasing the thermal contact area between the sidewall part 12a and the heat pipe 81, and thus, increasing the heat dissipation efficiency of the heat dissipation structure 1a to the heat pipe 81.

In addition, in this embodiment, the sidewall parts 12a located between and connected to the mount portions 20a and the cover part 11a of the heat dissipation structure 1a are absent of any holes or hollow structures. Furthermore, the bend portions 13a located between the mount portions 20a and the sidewall parts 12a are absent of any holes or hollow structures.

In specific, said “absent of any holes or hollow structures” refers to that there is no through hole or channel passing through opposite surfaces of one component. Therefore, each of the sidewall parts 12a has a solid body located between opposite ends of the cover part 11a. In addition, the cover part 11a has a solid body located between the opposite ends of the cover part 11a. Said “solid body” refers to that there is absent of any holes in a specified area/region. Accordingly, compared with the conventional heat dissipation structure with hollows or holes at the sidewall or the bend thereof after a bending process, the heat dissipation structure 1a in this embodiment can achieve higher heat dissipation efficiency to the heat pipe 81.

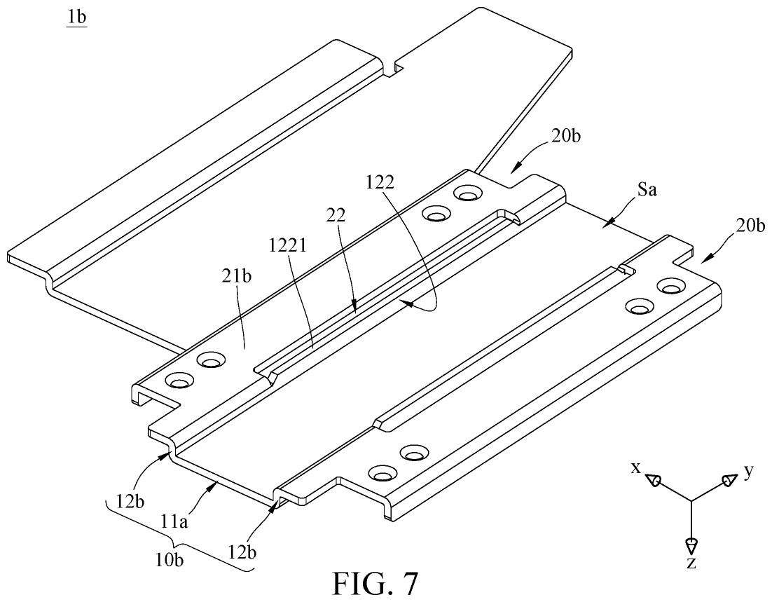

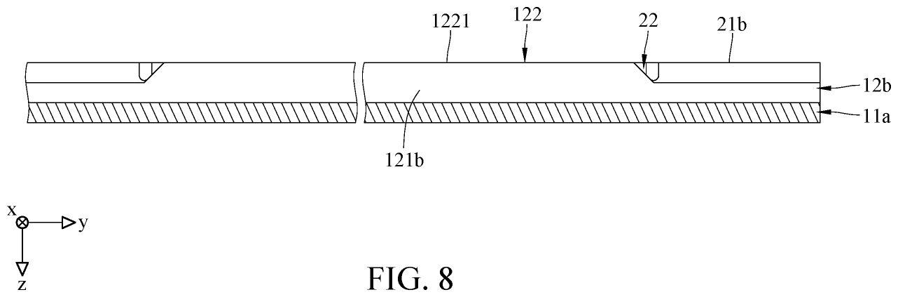

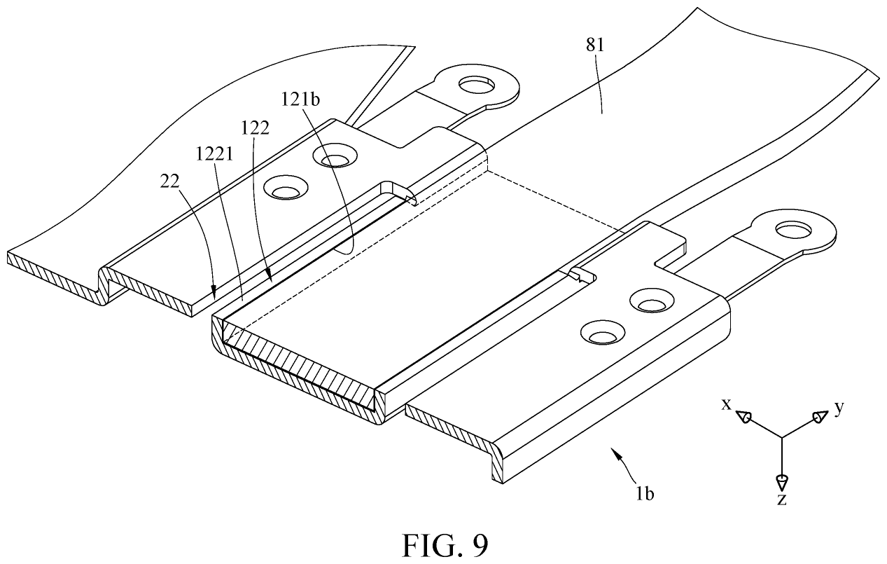

The above described heat dissipation structure of the present disclosure is only an exemplary example, and the present disclosure is not limited thereto. For example, please refer to FIG. 7 to FIG. 9. Another embodiment of the disclosure provides a heat dissipation structure 1b, and the heat dissipation structure 1b is also applicable to the electronic component 83 and the PCB 84 so as to form a heat dissipation assembly. However, it should be stated that for the purpose of conciseness, the following paragraphs only introduce differences between this embodiment and the above described embodiment, and identical or similar features between the embodiments can be understood from the preceding corresponding paragraphs and will not be repeated. In addition, same reference numerals refer to same component or structure.

In this embodiment, the heat dissipation structure 1b may include an accommodation portion 10b and two mount portions 20b. The accommodation portion 10b is located between and connected to the mount portions 20b. The accommodation portion 10b may include the cover part 11a described above and two sidewall parts 12b. The cover part 11a is located between and connected to the sidewall parts 12b and can be connected to the mount portions 20b via the sidewall parts 12b; in other words, the sidewall parts 12b are located between and connected to the cover part 11a and the mount portions 20b, respectively.

The cover part 11a and the sidewall parts 12b may be formed by, for example, a process of bending a sheet metal, so the cover part 11a can be at an angle to the sidewall parts 12b. For example, the cover part 11a may be substantially perpendicular to the sidewall parts 12b. From the perspective of the figures, the cover part 11a may be, for example, a plate structure extending in the XY-plane, and the sidewall parts 12b may be, for example, plate structures extending in the YZ-plane. According to the matching shape requirement of the accommodation portion 10b with the heat pipe 81, a width of the cover part 11a in the X-direction may be larger than a height of each of the sidewall parts 12b in the Z-direction.

In such configuration, the cover part 11a and the sidewall parts 12b can together surround and define an accommodation space Sb for receiving a part of the heat pipe 81. In specific, the sidewall parts 12b may have a sidewall surface 121b, and the sidewall surfaces 121b refer to surfaces of the sidewall parts 12b suitable to face toward or contact the heat pipe 81. The sidewall surfaces 121b may be substantially perpendicular to the cover surface 111 of the cover part 11a. From the perspective of the figures, the cover surface 111 may be, for example, a surface extending in the XY-plane, and the sidewall surfaces 121b may be, for example, surfaces extending in the YZ-plane.

The accommodation space Sb may be surrounded and defined by the cover surface 111 and the sidewall surfaces 121b, which is a space of the accommodation portion 10b configured to receive a part of the heat pipe 81. When at least a part of the heat pipe 81 is accommodated in the accommodation space Sb, the sidewall surfaces 121b of the sidewall parts 12b and the cover surface 111 of the cover part 11a may be in thermal contact with different surfaces of the heat pipe 81, respectively.

In addition, the sidewall parts 12b and the mount portions 20b may also be formed by, for example, a process of bending a sheet metal. As a result, the sidewall parts 12b can be at an angle to the mount portions 20b. For example, the sidewall parts 12b may be substantially perpendicular to the mount portions 20b. From the perspective of the figures, the mount portions 20b may be, for example, plate structures extending in the XY-plane, and the mount surfaces 21b of the mount portions 20b may be, for example, surfaces extending in the XY-plane. In such arrangement, the sidewall surfaces 121b of the sidewall parts 12b may be substantially perpendicular to the mount surfaces 21b of the mount portions 20b, and the cover surface 111 of the cover part 11a may be substantially parallel to the mount surfaces 21b of the mount portions 20b.

Moreover, in this embodiment, each of the sidewall parts 12b may include an upright section 122. The formation of the upright sections 122 can be achieved, for example, by punching slots 22 that penetrate through the mount surfaces 21b on the mount portions 20b, and then performing a sheet metal bending process on the sidewall parts 12b and the mount portions 20b. Therefore, an extension direction of the slots 22 is the same as an extension direction of the sidewall parts 12b, the upright sections 122 are located between the slots 22, and the upright sections 122 each has a cut surface 1221 left after the stamping process of forming the slots 22. As shown in the figures, the upright sections 122 may be, for example, upright plate structures extending in the XY-plane without any bends or fillets. In such configuration, when the heat dissipation structure 1b receives a part of the heat pipe 81, the sidewall surfaces 121b at the upright sections 122 provide larger and flatter surfaces on lateral sides of the heat pipe 81 to be in thermal contact with the heat pipe 81, thereby ensuring or even improving the heat dissipation efficiency of the heat dissipation structure 1b to the heat pipe 81.

Additionally, in this embodiment, the sidewall part 12b located between and connected to the mount portion 20b and the cover part 11a is absent of any slots or hollow structures. Accordingly, compared with the conventional heat dissipation structure with hollows or holes at the sidewall thereof after a bending process, the heat dissipation structure 1b in this embodiment can have a larger thermal contact area to contact the heat pipe 81 so as to achieve higher heat dissipation efficiency to the heat pipe 81. However, the disclosure is not limited to the above described embodiment.

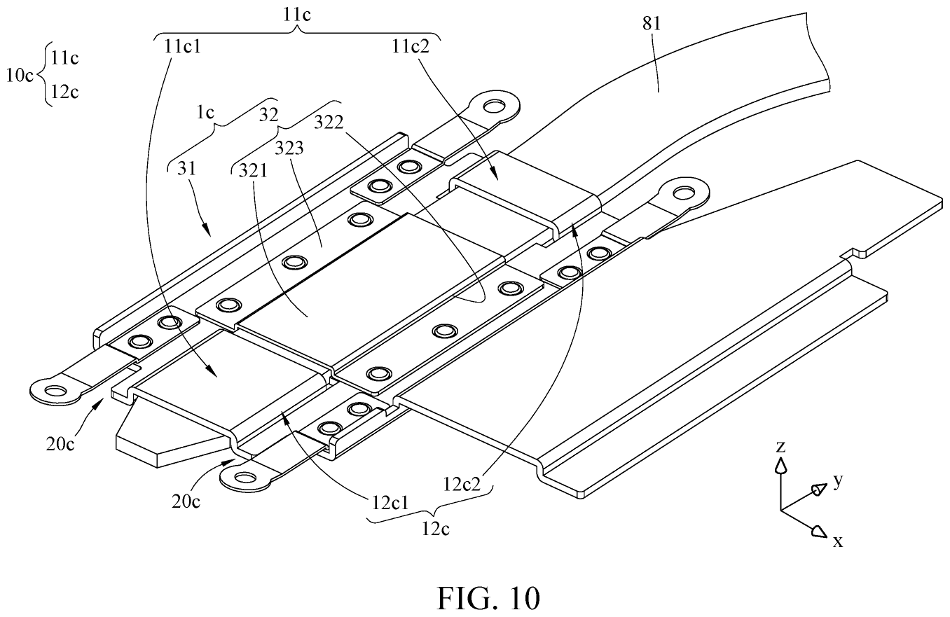

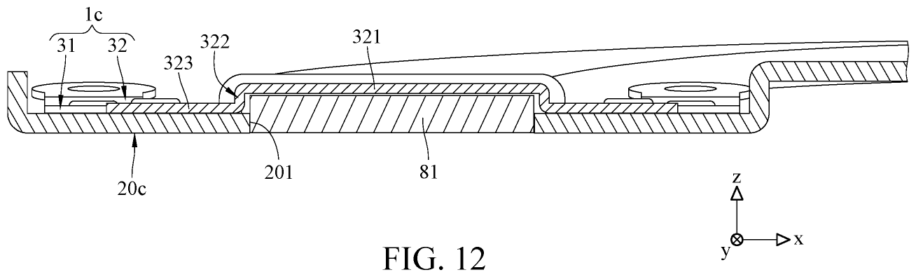

For example, please refer to FIG. 10 to FIG. 12. Another embodiment of the disclosure provides a heat dissipation structure 1c, and the heat dissipation structure 1c is also applicable to the electronic component 83 and the PCB 84 so as to form a heat dissipation assembly. However, it should be stated that for the purpose of conciseness, the following paragraphs only introduce differences between this embodiment and the above described embodiment, and identical or similar features between the embodiments can be understood from the preceding corresponding paragraphs and will not be repeated. In addition, same reference numerals refer to same component or structure.

In this embodiment, the heat dissipation structure 1c may include a base component 31 and a cap 32. The cap 32 may not be integrally formed with the base component 31. The base component 31 may include an accommodation portion 10c and two mount portions 20c. The accommodation portion 10c is located between and connected to the mount portions 20c. The accommodation portion 10c may include a cover part 11c and two sidewall parts 12c. The cover part 11c is located between and connected to the sidewall parts 12c and can be connected to the mount portions 20c via the sidewall parts 12c; in other words, the sidewall parts 12c are located between and connected to the cover part 11c and the mount portions 20c, respectively.

Furthermore, in this embodiment, the cover part 11c may include a first covering section 11c1 and a second covering section 11c2. Each of the sidewall parts 12c may include a first sidewall section 12c1 and a second sidewall section 12c2. The first covering section 11c1 and the second covering section 11c2 are spaced apart from each other. The first covering section 11c1 may be integrally formed between the mount portions 20c via the first sidewall sections 12c1. The second covering section 11c2 may be integrally formed between the mount portions 20c via the second sidewall sections 12c2. The mount portions 20c may be spaced apart from each other via the first covering section 11c1 and the second covering section 11c2. In such configuration, the first covering section 11c1, the second covering section 11c2 and edges of the mount portions 20c may together surround and form a hollow structure 311; that is, the hollow structure 311 may be located at the cover part 11c and extend between the mount portions 20c.

The formation of the base component 31 can be achieved, for example, by bending a single sheet metal into a basic configuration, and then, forming the hollow structure 311 by a stamping process. In this embodiment, the base component 31 may have a cut surface 201 having a smooth shape at each of the mount portions 20c left after the stamping process of forming the hollow structure 311. On the other hand, the cap 32 may be a unitary structure formed of a single piece. The cap 32 may include a cap covering section 321, two cap sidewall sections 322 and two cap mounting sections 323. The cap covering section 321 is located between and connected to the cap sidewall sections 322, and the cap covering section 321 is connected to the cap mounting sections 323 via the cap sidewall sections 322; in other words, the cap sidewall sections 322 may be located between the cap covering section 321 and the cap mounting sections 323, respectively. Additionally, the cap mounting sections 323 are suitable to be fixed to the mount portions 20c of the base component 31 by any suitable means, such as screws or bolts, so as to cover or shield at least a part of the hollow structure 311.

The formation of the cap 32 can be achieved, for example, by bending a single sheet metal. Accordingly, in this embodiment, the heat dissipation structure 1c is formed by two separate components that are assembled with each other, and the hollow structure 311 of the base component 31 can be covered by the additional cap 32. Therefore, a sufficient thermal contact area between the base component 31 and the heat pipe 81 and a sufficient thermal contact area between the cap 32 and the heat pipe 81 can be formed. As a result, compared with the conventional heat dissipation structure with hollows or holes at the sidewall or bend thereof after a bending process, the heat dissipation structure 1c in this embodiment can have a larger thermal contact area with the heat pipe 81 so as to achieve higher heat dissipation efficiency to the heat pipe 81.

In addition, when the heat dissipation structure 1c receives a part of the heat pipe 81, not only the first covering section 11c1, the second covering section 11c2, the first sidewall sections 12c1 and the second sidewall sections 12c2 of the base component 31 and the cap covering section 321 and the cap sidewall sections 322 of the cap 32 can be in thermal contact with the heat pipe 81, but also the mount portions 20c of the base component 31 can also provide the smoother cut surface 201 to be in thermal contact with the heat pipe 81, thereby ensuring or even improving the heat dissipation efficiency of the heat dissipation structure 1c to the heat pipe 81. However, the disclosure is not limited to the above described embodiment.

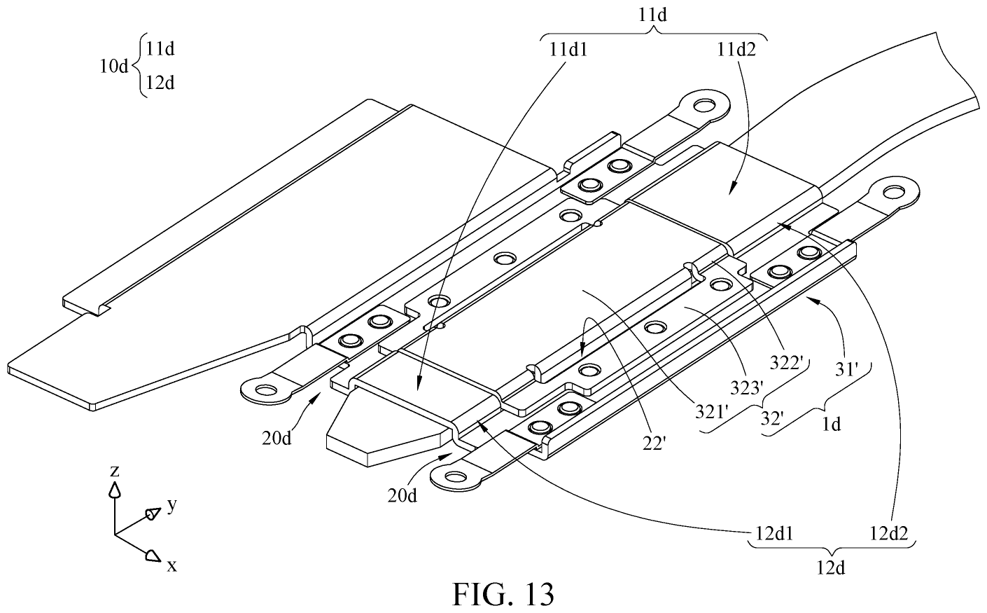

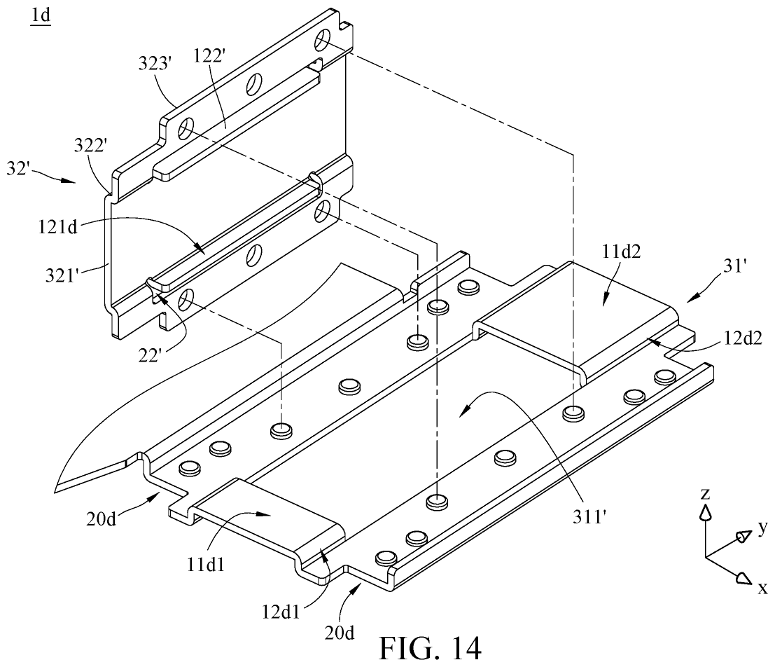

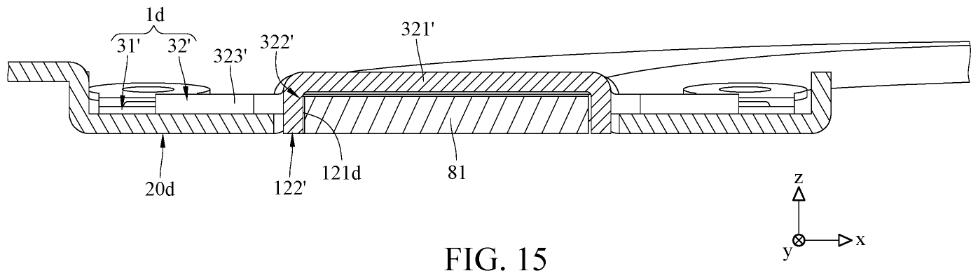

For example, please refer to FIG. 13 to FIG. 15. Another embodiment of the disclosure provides a heat dissipation structure 1d, and the heat dissipation structure 1d is also applicable to the electronic component 83 and the PCB 84 as described above so as to form a heat dissipation assembly. However, it should be stated that for the purpose of conciseness, the following paragraphs only introduce differences between this embodiment and the above described embodiment, and identical or similar features between the embodiments can be understood from the preceding corresponding paragraphs and will not be repeated. In addition, same reference numerals refer to same component or structure.

In this embodiment, the heat dissipation structure 1d may include a base component 31′ and a cap 32′. The base component 31′ may include an accommodation portion 10d and two mount portions 20d. The accommodation portion 10d is located between and connected to the mount portions 20d. The accommodation portion 10d may include a cover part 11d and two sidewall parts 12d. The cover part 11d is located between and connected to the sidewall parts 12d, and the cover part 11d is connected to the mount portions 20d via the sidewall parts 12d; in other words, the sidewall parts 12d is located between and connected to the cover part 11d and the mount portions 20d, respectively.

Furthermore, in this embodiment, the cover part 11d may include a first covering section 11d1 and a second covering section 11d2. The sidewall parts 12d may include a first sidewall section 12d1 and a second sidewall section 12d2. In addition, the first covering section 11d1 and the second covering section 11d2 are spaced apart from each other. The first covering section 11d1 may be integrally formed between the mount portions 20d via the first sidewall sections 12d1. The second covering section 11d2 may be integrally formed between the mount portions 20d via the second sidewall sections 12d2. The mount portions 20d may be spaced apart from each other via the first covering section 11d1 and the second covering section 11d2. In such configuration, the first covering section 11d1, the second covering section 11d2 and edges of the mount portions 20d may together surround and form a hollow structure 311′; that is, the hollow structure 311′ may be located at the cover part 11d and extend between the mount portions 20d.

The formation of the base component 31′ can be achieved, for example, by bending a single sheet metal into a basic configuration, and then, forming the hollow structure 311′ by a stamping process. On the other hand, the cap 32′ may be a unitary structure formed of a single piece. The cap 32′ may include a cap covering section 321′, two cap sidewall sections 322′ and two cap mounting sections 323′. The cap covering section 321′ is located between and connected to the cap sidewall sections 322′, and the cap covering section 321′ is connected to the cap mounting sections 323′ via the cap sidewall sections 322′; in other words, the cap sidewall sections 322′ may be located between the cap covering section 321′ and the cap mounting sections 323′. Additionally, the cap mounting sections 323′ are suitable to be fixed to the mount portions 20d of the base component 31′ by any suitable means, such as screws or bolts, so as to cover or shield at least a part of the hollow structure 311′. The formation of the cap 32′ can be achieved, for example, by bending a single sheet metal.

In addition, in this embodiment, the cap sidewall sections 322′ may include an upright sections 122′. The formation of the upright sections 122′ can be achieved, for example, by punching slots 22′ that penetrate through the cap mounting sections 323′, and then performing a sheet metal bending process on the cap sidewall sections 322′ and the cap mounting sections 323′. Therefore, the upright sections 122′ are located between the slots 22′.

In addition, as shown in the figures, ends of the upright sections 122′ may be flush with surfaces of the mount portions 20d. Accordingly, in this embodiment, the heat dissipation structure 1d is formed by two separate components that are assembled with each other, and the hollow structure 311′ of the base component 31′ can be covered by the additional cap 32′. Therefore, a sufficient thermal contact area between the base component 31′ and the heat pipe 81 and a sufficient thermal contact area between the cap 32′ and the heat pipe 81 can be formed. As a result, compared with the conventional heat dissipation structure with hollows or holes at the sidewall or bend thereof after a bending process, the heat dissipation structure 1d in this embodiment can have a larger thermal contact area with the heat pipe 81 so as to achieve higher heat dissipation efficiency to the heat pipe 81.

In addition, when the heat dissipation structure 1d receives a part of the heat pipe 81, not only the first covering section 11d1, the second covering section 11d2, the first sidewall sections 12d1 and the second sidewall sections 12d2 of the base component 31′ and the cap covering section 321′ and the cap sidewall sections 322′ of the cap 32′ can be in thermal contact with the heat pipe 81, but also sidewall surfaces 121d at the upright sections 122′ can also provide larger and flatter surfaces to thermally contact lateral sides of the heat pipe 81, thereby ensuring or even improving the heat dissipation efficiency of the heat dissipation structure 1d to the heat pipe 81.

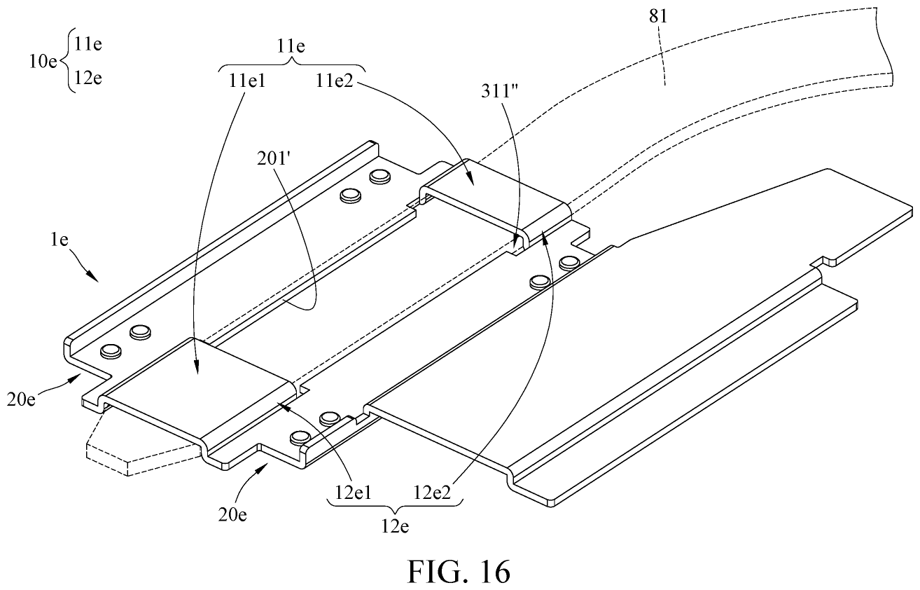

The disclosure is not limited to the two-piece heat dissipation structure as shown in FIG. 10 to FIG. 15 as described above. For example, please refer to FIG. 16. Another embodiment of the disclosure provides a heat dissipation structure 1e, and the heat dissipation structure 1e is also applicable to the electronic component 83 and the PCB 84 as described above so as to form a heat dissipation assembly. However, it should be stated that for the purpose of conciseness, the following paragraphs only introduce differences between this embodiment and the above described embodiment, and identical or similar features between the embodiments can be understood from the preceding corresponding paragraphs and will not be repeated. In addition, same reference numerals refer to same component or structure.

As shown in the figures, the heat dissipation structure 1e may include an accommodation portion 10e and two mount portions 20e. The accommodation portion 10e is located between and connected to the mount portions 20e. The accommodation portion 10e may include a cover part 11e and two sidewall parts 12e. The cover part 11e is located between and connected to the sidewall parts 12e, and the cover part 11e is connected to the mount portions 20e via the sidewall parts 12e; in other words, the sidewall parts 12e are located between and connected to the cover part 11e and the mount portions 20e, respectively.

Furthermore, the cover part 11e may include a first covering section 11e1 and a second covering section 11e2. Each of the sidewall parts 12e may include a first sidewall section 12e1 and a second sidewall section 12e2. The first covering section 11e1 and the second covering section 11e2 are spaced apart from each other. The first covering section 11e1 may be integrally formed between the mount portions 20e via the first sidewall sections 12e1. The second covering section 11e2 may be integrally formed between the mount portions 20e via the second sidewall sections 12e2.

In such configuration, the first covering section 11e1, the first sidewall sections 12e1, the second covering section 11e2, the second sidewall sections 12e2 and the mount portions 20e are integrally formed to be the heat dissipation structure 1e. The heat dissipation structure 1e has a hollow structure 311″. As shown in the figure, the hollow structure 311″ extends between the mount portions 20e, and the hollow structure 311″ is surrounded and formed by the first covering section 11e1, the second covering section 11e2 and edges of the mount portions 20e together; that is, the hollow structure 311′ extends among the first covering section 11e1, the second covering section 11e2 and the mount portions 20e; in other words, the hollow structure 311′ can be located at the cover part 11e and extend between the mount portions 20e.

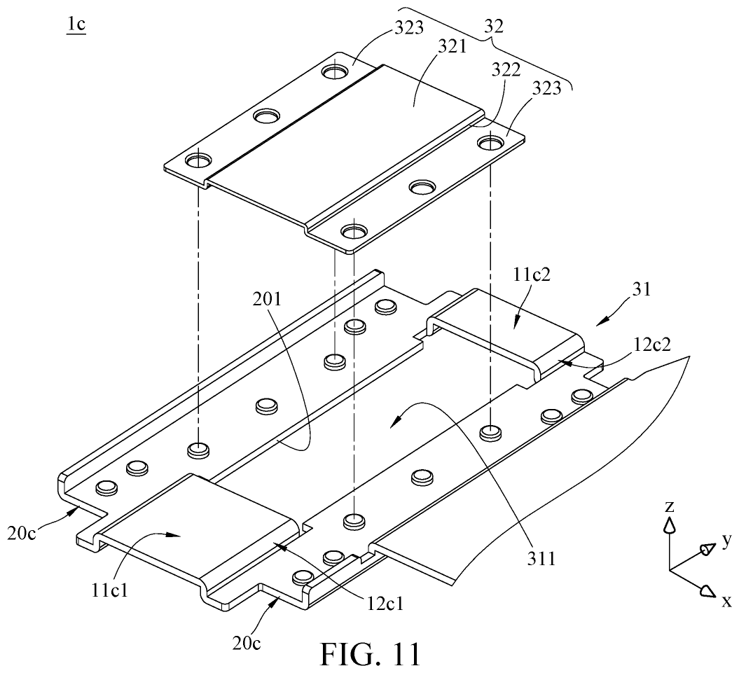

Accordingly, the formation of the heat dissipation structure 1e can be achieved, for example, by bending a single sheet metal into a basic configuration, and then, forming the hollow structure 311″ by a stamping process. Therefore, the heat dissipation structure 1e may have a cut surface 201′ having a smooth shape at each of the mount portions 20e left after the stamping process of forming the hollow structure 311′. Compared with the aforementioned embodiment of FIG. 11, the heat dissipation structure 1e may be, for example, the heat dissipation structure 1c without the cap 32, and only adopts the base component 31 for installation and heat dissipation for the heat pipe 81, allowing the heat dissipation structure 1e to achieve required heat dissipation performance by increasing the thermal contact area between the heat pipe 81 and air at lower material costs.

In view of the above description, a compression treatment can be optionally performed on the bend portions so as to increase the thermal contact area between the heat dissipation structure and the heat pipe, larger and flatter surfaces can be provided by forming the upright sections on the sidewall parts to enable the larger and flatter surfaces of the sidewall parts to thermally contact the lateral sides of the heat pipe, the heat dissipation structure can be modified into two pieces so as to provide smoother cut surfaces on the mount portions for increasing the thermal contact area between the mount portions and the heat pipe, or the hollow structure extending between the mount portions can be used to increase the contact area between the heat pipe and air so as to achieve required heat dissipation performance, which are all capable of addressing the problem of deteriorated heat dissipation efficiency of the conventional heat dissipation structure to the heat pipe due to the thermal contact area therebetween being reduced by the fillets formed after the bending process.

The embodiments were chosen and described in order to best explain the principles of the disclosure and its practical applications, to thereby enable others skilled in the art to best utilize the disclosure and various embodiments with various modifications as are suited to the particular use contemplated. It is intended that the scope of the disclosure be defined by the following claims and their equivalents.

What is claimed is:

1. A heat dissipation structure, comprising:
an accommodation portion comprising a cover part and two sidewall parts, and the cover part located between and connected to the two sidewall parts; and
two mount portions, wherein the cover part is located between and connected to the two mount portions via the two sidewall parts, and each of the two sidewall parts has a solid body located between opposite ends of the cover part.

2. The heat dissipation structure according to claim 1, wherein the cover part has a solid body located between the opposite ends of the cover part.

3. The heat dissipation structure according to claim 1, wherein a section of each of the two sidewall parts located between the opposite ends of the cover part is absent of any holes.

4. The heat dissipation structure according to claim 2, wherein the cover part is absent of any holes.

5. The heat dissipation structure according to claim 1, wherein each of the two sidewall parts comprises an upright section, and each of the upright sections has a cut surface.

6. The heat dissipation structure according to claim 5, wherein each of the two mount portions has a slot, and the upright sections are located between the slots.

7. The heat dissipation structure according to claim 6, wherein an extension direction of the slots is same as an extension direction of the two sidewall parts.

8. A heat dissipation structure, comprising:
an accommodation portion comprising a cover part and two sidewall parts, and the cover part located between and connected to the two sidewall parts; and
two mount portions, wherein the cover part is located between and connected to the two mount portions via the two sidewall parts;
wherein the heat dissipation structure has a hollow structure located at the cover part and extending between the two mount portions.

9. The heat dissipation structure according to claim 8, wherein the cover part comprises a first covering section and a second covering section that are spaced apart from each other, the two mount portions are spaced apart from each other by the first covering section and the second covering section, and the two mount portions, the first covering section and the second covering section together surround and form the hollow structure.

10. The heat dissipation structure according to claim 8, wherein each of the two mount portions has a cut surface.

11. The heat dissipation structure according to claim 8, further comprising a cap, wherein the cap comprises a cap covering section, two cap sidewall sections and two cap mounting sections, the cap covering section is located between and connected to the two cap mounting sections via the two cap sidewall sections, the two cap mounting sections are fixed to the two mount portions, respectively, and the cap covers at least a part of the hollow structure.

12. The heat dissipation structure according to claim 11, wherein the cap is not integrally formed with the two mount portions.

13. The heat dissipation structure according to claim 11, wherein each of the two cap mounting sections has a slot.

14. The heat dissipation structure according to claim 13, wherein an extension direction of the slots is same as an extension direction of the two cap sidewall sections.

15. The heat dissipation structure according to claim 11, wherein the two cap mounting sections are stacked on the two mount portions, respectively.

16. The heat dissipation structure according to claim 11, wherein each of the two cap sidewall sections has an upright section, and at least a part of each of the upright sections is located between the two mount portions.

17. The heat dissipation structure according to claim 16, wherein the upright sections are located on opposite sides of the hollow structure of the heat dissipation structure, respectively.

18. The heat dissipation structure according to claim 16, wherein ends of the upright sections are flush with surfaces of the two mount portions.

19. A heat dissipation assembly, comprising:
a heat dissipation structure comprising:
an accommodation portion comprising a cover part and two sidewall parts, and the cover part located between and connected to the two sidewall parts; and
two mount portions, wherein the cover part is located between and connected to the two mount portions via the two sidewall parts, and a section of each of the two sidewall parts located between opposite ends of the cover part is absent of any holes, and the cover part is absent of any holes;
a heat pipe partially disposed in the accommodation portion of the heat dissipation structure and in thermal contact with the cover part and the two sidewall parts; and
a heat sink in thermal contact with the heat pipe.

20. The heat dissipation assembly according to claim 19, wherein the accommodation portion and the heat sink are located on opposite ends of the heat pipe, respectively.
